(19) United States
(12) Patent Application Publication
(10) Pub. No.: US 2006/0205097 A1
(43) Pub. Date: Sep. 14, 2006

(54) Methods of manufacturing a crystal-oriented ceramic and of manufacturing a ceramic laminate

(75) Inventors: Shige Kadotani, Chita-gun (JP); Akio Iwase, Nishio-city (JP)

Correspondence Address: HARNESS, DICKEY & PIERCE, P.L.C., P.O. BOX 828, BLOOMFIELD HILLS, MI, 48303, US

(73) Assignee: DENSO Corporation, Kariya-city (JP)

(21) Appl. No.: 11/373,877

(22) Filed: Mar. 10, 2006

(30) Foreign Application Priority Data
Mar. 11, 2005 (JP) 2005-069798

(51) Int. Cl. H01L 21/00; H01L 21/302; H01L 21/461

(52) U.S. Cl. 438/3; 438/722

(57) ABSTRACT

A method for manufacturing a crystal-oriented ceramic comprising a sheet-making step, a crystallization-promoting layer-forming step and a calcining step is provided. At the sheet-making step, a green sheet 1 is made. At the crystallization-promoting layer-forming step, a crystallization-promoting layer 15 containing crystallization-promoting material particles 151 is formed so as to contact the green sheet 1. At the calcining step, the green sheet is calcined. A method for manufacturing a ceramic laminate comprising a laminate-making step and a calcining step is provided. At the laminate-making step, a laminate is made, where green sheets and electrode-printed layers are stacked. The crystallization-promoting layer, containing the crystallization-promoting material particles, which allow crystal grains in a polycrystalline substance to grow during calcining, is formed so as to contact the green sheet. At the calcining step, the laminate is calcined.

### TECHNICAL FIELD

The present invention relates to a method of manufacturing a crystal-oriented ceramic, which are composed of a polycrystalline substance comprising a perovskite structure (ABO₃) as the main component, and a method of manufacturing a ceramic laminate in which the crystal-oriented ceramics and internal electrode layers are laminated.

### BACKGROUND ART

In the past, piezoelectric ceramics have been widely applied in the fields of electronics and mechatronics. Piezoelectric ceramics are subjected to a so-called polarization treatment in which an electric field is applied to ferroelectric ceramics to orient the direction of the ferroelectric domains in a fixed direction. In the case of piezoelectric ceramics, in order to orient spontaneous polarization in a fixed direction by polarization treatment, an isotropic perovskite crystal structure is advantageous, as this allows the direction of spontaneous polarization to be three-dimensional. Consequently, the majority of piezoelectric ceramics in practical use are isotopic perovskite ferroelectric ceramics.

There is a ceramic laminate in which piezoelectric ceramics and internal electrode layers are alternately stacked. The ceramic laminate is utilized as a laminate-type piezoelectric element, for example, in an injector for injecting fuel in an automobile. It is required to develop a laminate-type piezoelectric element with a higher power in applications of the injector and the like.

Previously, a crystal-oriented ceramic, in which a specific crystal plane is oriented, have been developed as piezoelectric ceramics in order to increase the power of the laminate-type piezoelectric element (see Japanese unexamined patent publications No. 11-60333, No. 11-199327, No. 2001-106568 and No. 2003-12373).

On the occasion of manufacturing a crystal-oriented ceramic, host materials in the form of a plate have been utilized as seed crystals to allow crystals to orient by using them as templates.

Concretely, as shown in FIG. 25, crystals can be oriented using the seed crystals 95 as the templates to obtain a crystal-oriented ceramic, by forming slurry comprising a piezoelectric material and templates (seed crystals 95) in the form of a sheet to prepare a green sheet 9, drying and calcining the green sheet 9.

However, as shown in the same Figure, in a method of manufacturing a crystal-oriented ceramic using templates, when the green sheet 9 is prepared, it is difficult to uniformly disperse seed crystals 95, which are templates, in the slurry of a piezoelectric material, and there has been a potential for non-uniformity to occur in a dispersing state of the seed crystals 95 within the green sheet 9. As the seed crystals 95 were generally larger than particles of the piezoelectric material, the seed crystals 95 have easily precipitated, and it has been difficult to disperse the seed crystals 95 in the whole of the green sheet 9. Therefore, in the crystal-oriented ceramics obtained after calcining, non-uniformity of piezoelectric properties occurred, thus there has been a potential for desired piezoelectric properties to be unobtainable. As a result, there has been a problem that crystal-oriented ceramics could not offer a sufficient power, even in a case of applying them to piezoelectric ceramics of the laminate-type piezoelectric element.

As shown in FIG. 26, in a method of manufacturing crystal-oriented ceramics using templates, when the green sheet 9 is dried after being made, gaps 99 easily occur around the seed crystals 95. Such gaps 99 become a cause of allowing cracks and the like to occur in the crystal-oriented ceramics, and there is a potential for piezoelectric properties of the crystal-oriented ceramics to decrease. As shrinkage factors of the piezoelectric material and the templates are different at the time of calcining, there has been a problem of easily causing micro spaces and internal stresses.

Further, in a conventional method of manufacturing the crystal-oriented ceramics using templates, there have been problems of taking a long time for calcining and increasing a manufacturing cost.

### SUMMARY OF INVENTIONS

The present invention has been achieved of by considering such current problems, and provides a new method of manufacturing crystal-oriented ceramics whereby the crystal-oriented ceramics can be manufactured in a short time, and a method of manufacturing a ceramic laminate.

A first present invention provides a method for manufacturing a crystal-oriented ceramic, which is composed of a polycrystalline substance comprising a perovskite structure (ABO₃) as a main component, and in which a crystal plane of each of crystal grains constituting the polycrystalline substance is oriented, comprising

a sheet-making step of making a green sheet composed of a piezoelectric material which produces the polycrystalline substance of the perovskite structure by being calcined,

a crystallization-promoting layer-forming step of forming a crystallization-promoting layer comprising crystallization-promoting material particles, which allow crystal grains in the polycrystalline substance to grow at a time of calcining, so as to be in contact with the green sheet, and

a calcining step of making the crystal-oriented ceramic by calcining the green sheets where the crystallization-promoting layer was formed.

In the method for manufacturing a crystal-oriented ceramic of the first invention, the sheet-making step, the crystallization-promoting layer-forming step and the calcining step are performed. At the crystallization-promoting layer-forming step, the crystallization-promoting layer comprising crystallization-promoting material particles, which allow crystal grains in the polycrystalline substance to grow at the time of calcining, is formed so as to be in contact with the green sheet.

Therefore, at the calcining step, polycrystalline substances with the perovskite structure are formed from the piezoelectric material in the green sheet, and crystal grains in the polycrystalline substances can be grown via the crystallization-promoting material particles. As a result, an orientation degree of the polycrystalline substance can be increased, and a crystal plane of each of the crystal grains of the polycrystalline substance can be oriented.

At the crystallization-promoting layer-forming step, the crystallization-promoting layer is formed so as to be in contact with the green sheet. In other words, for example, the crystallization-promoting layer can be formed on a surface of the green sheet. However, the growth of the crystal grains of the polycrystalline substance at the calcining step is promoted not only at portions contact with the crystallization-promoting layer of the green sheet, but also at other portions such as inside of the green sheet. Therefore, at the calcining step, the crystal grains at the surface and the inside of the crystal-oriented ceramic can be entirely oriented, and a crystal-oriented ceramic with high orientation degree can be obtained.

Further, the crystal-oriented ceramic of the first present invention can make a calcining time of the calcining step shorter than in a method using conventional templates. In other words, in a conventional method of making a crystal-oriented ceramic by calcining a green sheet where templates are dispersed, it has been necessary to maintain the green sheet at a desired calcining temperature for as long as 5 hours in order to obtain the crystal-oriented ceramic.

On the other hand, the method of manufacturing of the first present invention, the crystal-oriented ceramic can be made in a short calcining time such as 2 hours. Further, a step of making templates which has conventionally taken a very long time can be omitted.

Therefore, the crystal-oriented ceramic can be made in a shorter time than the conventional method, and a manufacturing cost can be reduced.

As described above, based on the first present invention, a new method of manufacturing the crystal-oriented ceramic can be provided, whereby it can be manufactured within a short time.

A second present invention is a method for manufacturing a ceramic laminate, which is composed of a polycrystalline substance comprising a perovskite structure (ABO₃) as a main component, and in which crystal-oriented ceramic layers, wherein a specific crystal plane of each of crystal grains constituting the polycrystalline substance is oriented, and internal electrode layers are alternately stacked, comprising

a laminate-making step of making a laminate in which a green sheet composed of a piezoelectric material, which produces the polycrystalline substance of the perovskite structure by being calcining, and electrode-printed layers, which form the internal electrode layers by calcining, are stacked, and

a calcining step of making the ceramic laminate by calcining the laminate,

and, at the laminate-making step, a crystallization-promoting layer containing crystallization-promoting material particles, which allow crystal grains in the polycrystalline substance to grow at a time of calcining, is formed so as to be in contact with the green sheet.

In the second present invention, the laminate-making step and the calcining step are performed. At the laminate-making step, a laminate is formed, where green sheets composed of a piezoelectric material, which forms the polycrystalline substance of the perovskite structure by calcining, and electrode-printed layers, which form the internal electrode layers by calcining, are stacked. Further, the crystallization-promoting layer containing the crystallization-promoting material particles is formed so as to be in contact with the green sheet.

Therefore, at the calcining step, as in the case of the above first invention, polycrystalline substances with the perovskite structure can be formed from the piezoelectric material in the green sheets, and crystal grains in the polycrystalline substances can grow via the crystallization-promoting material particles. As a result, an orientation degree of the polycrystalline substance can be increased, and a crystal plane of each of the crystal grains of the polycrystalline substance can be oriented. At this time, the growth of the crystal grains of the polycrystalline substance is promoted via the crystallization-promoting material particles not only at portions contact with the crystallization-promoting layer of the green sheet, but also at other portions such as inside of the green sheet. Thereby, in the calcining step, the crystal grains of the crystal-oriented ceramic layer can be entirely oriented, and a crystal-oriented ceramic layer with high orientation degree can be obtained.

At the calcining step, as described above, the crystal-oriented ceramic layers can be formed, and the internal electrode layers can be formed from the electrode-printed layers.

As a result, the ceramic laminate can be manufactured, wherein the crystal-oriented ceramic layers in which a crystal plane of each of the crystal grains constituting the polycrystalline substance is oriented, and the internal electrode layers are alternately stacked. The ceramic laminate can exert a high power, since it has the crystal-oriented ceramic layer with an excellent orientation degree. Thus, the ceramic laminate can be suitably utilized, for example, in an injector for injecting fuel in an automobile.

Further, in the method for manufacturing a ceramic laminate of the second present invention, as in the case of the above first invention, it is possible to make a calcining time of the calcining step shorter than in a method with conventional templates. It also is possible to omit a step of making templates. Therefore, the ceramic laminate can be made in a shorter time, and at low cost.

### BRIEF DESCRIPTION OF THE DRAWINGS

FIG. 1 shows a drawing to illustrate a stacking state of a green sheet and a crystallization-promoting layer in Example 1.

FIG. 2 shows a drawing to illustrate a state of stacking green sheets having a crystallization-promoting layer in Example 1.

FIG. 3 shows a drawing to illustrate a laminate of crystal-oriented ceramics in Example 1.

FIG. 4 shows a drawing to illustrate an ultrasonic oscillator in Example 1.

FIG. 5 shows an electron microscope photograph at a magnification of 100 times showing a crystalline state of Sample E1 (using MgO₂ particles) in Example 1.

FIG. 6 shows an electron microscope photograph at a magnification of 100 times showing a crystalline state of Sample E2 (using SiC particles) in Example 1.

FIG. 7 shows an electron microscope photograph at a magnification of 100 times showing a crystalline state of Sample C1 (without crystallization-promoting material particle) in Example 1.

FIG. 8 shows a drawing to illustrate a stacking state of a green sheet containing template particles and a crystallization-promoting layer in Example 2.

FIG. 9 shows a drawing to illustrate a stacking state of a green sheet containing template particles and a separating layer in Example 2.

FIG. 10(a) shows an electron microscope photographs at a magnification of 50 times and FIG. 10(b) shows an electron microscope photographs at a magnification of 100 times, showing a crystalline state of Sample E3 (using MgO₂ particles) in Example 2.

FIG. 11(a) shows an electron microscope photographs at a magnification of 50 times and FIG. 11(b) shows an electron microscope photographs at a magnification of 100 times, showing a crystalline state of Sample E4 (using SiC particles) in Example 2.

FIG. 12(a) shows an electron microscope photographs at a magnification of 50 times and FIG. 12(b) shows an electron microscope photographs at a magnification of 100 times, showing a crystalline state of Sample E5 (using TiO₂ particles) in Example 2.

FIG. 13(a) shows an electron microscope photographs at a magnification of 50 times and FIG. 13(b) shows an electron microscope photographs at a magnification of 100 times, showing a crystalline state of Sample E6 (using Al₂O₃ particles) in Example 2.

FIG. 14(a) shows an electron microscope photographs at a magnification of 50 times and FIG. 14(b) shows an electron microscope photographs at a magnification of 100 times, showing a crystalline state of Sample E7 (using Si₃N₄ particles) in Example 2.

FIG. 15(a) shows an electron microscope photographs at a magnification of 50 times and FIG. 15(b) shows an electron microscope photographs at a magnification of 100 times, showing a crystalline state of Sample C2 (without crystallization-promoting material particle) in Example 2.

FIG. 16 shows a drawing to illustrate a stacking state of a green sheet and a crystallization-promoting layer in Example 3.

FIG. 17 shows a drawing to illustrate an entire configuration of a ceramic laminate in Example 4.

FIG. 18 shows a drawing to illustrate an entire configuration of a laminate in Example 4.

FIG. 19 shows a partially enlarged drawing to illustrate a configuration of a stacked part of a laminate in Example 4

FIG. 20 shows a drawing to illustrate a stacking state of a green sheet, a crystallization-promoting layer, an internal electrode layer, a spacer layer and an adhesive layer in Example 4.

FIG. 21 shows a drawing to illustrate a stacking state of a green sheet, an internal electrode layer, a spacer layer and an adhesive layer in Example 5.

FIG. 22 shows a partially enlarged drawing to illustrate a configuration of a stacked part of a laminate in Example 5

FIG. 23 shows a drawing to illustrate a stacking state of a green sheet, an internal electrode layer, a spacer layer and an adhesive layer in Example 6.

FIG. 24 shows a partially enlarged drawing to illustrate a configuration of a stacked part of a laminate in Example 6

FIG. 25 shows a drawing to illustrate a state where templates (seed crystals) precipitated in a green sheet.

FIG. 26 shows a drawing to illustrate a state where gaps occur around templates (seed crystals) in a green sheet.

### DETAILED DESCRIPTION

Examples of embodiments of the present invention will now be explained.

In the method for manufacturing of the first present invention, the crystal-oriented ceramic can be manufactured, which is composed of a polycrystalline substance comprising a perovskite structure (ABO₃) as the main component, and in which a crystal plane of each of the crystal grains constituting the polycrystalline substance is oriented. Further, in the method for manufacturing of the second present invention, the ceramic laminate can be manufactured, wherein the crystal-oriented ceramic layers in which the crystal plane of each of the crystal grains of the polycrystalline substance is oriented like the crystal-oriented ceramic of the first present invention, and the internal electrode layers are stacked.

The polycrystalline substances comprising a perovskite structure as the main component include, for example, a polycrystalline substance comprising an isotropic perovskite compound as a main phase.

The phrase “a crystal plane orients” means both of a state where each crystal grain is arranged so that specific crystal planes of a polycrystalline substance comprising the perovskite structure compound as a main component are in parallel each other (refer to such a state as “planar oriented” herein after), and a state where each crystal grain is oriented so that specific crystal planes is in parallel to an axis penetrates the polycrystalline substance (refer to such a state as “axial oriented” herein after).

In the first and second inventions, the crystallization-promoting layer containing the crystallization-promoting material particles, which allow crystal grains in the polycrystalline substance to grow at the time of calcining, is formed so as to be in contact with the green sheet. Concretely, for example, the crystallization-promoting layer can be formed at a surface (a sheet surface) of the green sheet. Alternatively, the crystallization-promoting layer can be formed at the inside of the green sheet in the form of a layer approximately in parallel with the sheet surface of the green sheet.

It is preferred that the crystallization-promoting material particles are composed of one or more selected from TiO₂, MgO₂, Al₂O₃, Si₃N₄ and SiC.

In this case, at the calcining step after the crystallization-promoting layer-forming step, it is possible to allow the crystal grains in the polycrystalline substance to fully grow to form the crystal-oriented ceramic (the crystal-oriented ceramic layer) with a high orientation degree.

It is preferred that the crystallization-promoting layer contains the crystallization-promoting material particles at 2-10 wt %.

If the content of the crystallization-promoting material particles is less than 2 wt %, the orientation degree of the obtained crystal-oriented ceramic (crystal-oriented ceramic layer) becomes to be insufficient, and there is a potential for a sufficient power not to be exerted, when it is applied to an injector of an automobile and the like. On the other hand, when the content of the crystallization-promoting material particles is beyond 10 wt %, an effect appropriate to a loading of the crystallization-promoting material particles cannot be obtained, and there is a potential for a cost of the crystallization-promoting material particles to uselessly increase. Further, there is a potential for the excessively added crystallization-promoting material particles to adversely affect piezoelectric properties of the crystal-oriented ceramic (the crystal-oriented ceramic layer).

In the crystal-oriented ceramic of the first invention, the crystallization-promoting material particles of the crystallization-promoting layer can be removed after making the crystal-oriented ceramic. However, when the crystallization-promoting material particles are contained at an excessive amount beyond 10 wt % as described above, there is a potential for a process of removing them to become difficult.

In the ceramic laminate of the second invention, when the crystallization-promoting material particles are contained at an excessive amount beyond 10 wt % as described above, there is a potential for a sufficient power not to be exerted, since unreacted crystallization-promoting material particles remain.

In the first and second inventions, it is preferred that the content of the crystallization-promoting material particles in the crystallization-promoting layer is 0.1-2 parts by weight per 100 parts by weight of the piezoelectric material contained in the green sheet.

When it is less than 0.1 parts by weight, there is a potential for the orientation degree of the crystal-oriented ceramic (the crystal-oriented ceramic layer) to become insufficient. On the other hand, when it is beyond 2 parts by weight, there is a potential for the cost of the crystallization-promoting material particles to uselessly increase. Further, in this case, there is a potential for an excessive amount of crystallization-promoting material particles to adversely affect piezoelectric properties of the crystal-oriented ceramic (the crystal-oriented ceramic layer).

It is preferred that an average diameter of the crystallization-promoting material particles is 0.2-2 μm.

When the average diameter of the crystallization-promoting material particles is less than 0.2 μm, there is a potential for the manufacturing cost to increase. On the other hand, when it is beyond 2 μm, there is a potential for faulty dispersion to become easily occurring.

It is preferred that the green sheet is composed of a perovskite compound, and contains template particles in which a crystal plane having lattice coherency with a specific crystal plane of each of the crystal grains constituting the polycrystalline substance is oriented.

In this case, the orientation degree can be more increased, since crystal growth can be synergistically promoted by both of the crystallization-promoting material particles and the template particles.

The lattice coherency can be represented with a lattice coherency rate.

In order to explain the lattice coherency, for example, a case is explained where the template particles are metal oxide. In other words, when in a two dimensional crystal lattice at an orientation plane of the template particle, for example, a lattice point composed of an oxygen atom or a lattice point composed of a metal atom, and a lattice point composed of an oxygen atom in the two dimensional crystal lattice of a specific crystal plane orientating in the polycrystalline substance or a lattice point composed of a metal atom have similitude relations, there is a lattice coherency between both of them.

The lattice coherency rate expresses a value on a percentage basis obtained by dividing an absolute value of a difference between the orientation plane at the template particle and a lattice dimension at a similitude position of the specific crystal plane orientating at the polycrystalline substance by a lattice dimension of an orientation plane of the template particle.

The lattice dimension is a distance between lattice points at the two dimensional crystal lattice of one crystal plane, and can be measured by analyzing a crystal structure by an X-ray diffraction, an electron beam diffraction or the like. In general, as the lattice coherency rate becomes smaller, the lattice coherency of the template particle with the specific crystal plane orientating at the polycrystalline substance becomes higher, and the template particle can function as a good template.

The content of the templates in the green sheet is preferably 0.5-5 wt %. When it is less than 0.5 wt %, there is a potential for an effect of improving the above-described orientation degree by template particles not to be obtained. On the other hand, when it is beyond 5 wt %, there is a potential for micro spaces or inner stresses to occur, or for cracks to occur.

In the first invention, the sheet-making step, the crystallization-promoting layer-forming step and the calcining step are performed.

At the sheet-making step, the green sheet composed of the piezoelectric material, which forms the polycrystalline substance of the perovskite structure, is made by calcining.

The green sheet can be made, for example, by applying the piezoelectric material in a slurry state on a film with a desired thickness by a doctor blade method and the like. It also can be made by other methods such as an extrusion molding method and the like.

At the crystallization-promoting layer-forming step, the crystallization-promoting layer comprising crystallization-promoting material particles, which allow crystal grains in the polycrystalline substance to grow at the time of calcining, is formed so as to be in contact with the green sheet.

Concretely, the crystallization-promoting layer can be formed, for example, by printing a coating material comprising the crystallization-promoting material particles on at least one surface of the green sheet.

The crystallization-promoting layer also can be formed inside of the green sheet or between two or more sheets of the green sheet.

Concretely, the crystallization-promoting layer can be formed, for example by preparing a green sheet, forming the crystallization-promoting layer on the green sheet, and further stackedly forming a green sheet on the crystallization-promoting layer.

It is preferred that the crystallization-promoting layer contains a piezoelectric material with approximately the same components as in the piezoelectric material of the green sheet.

In this case, the crystal-oriented ceramic with approximately uniform components and with little non-uniformity of piezoelectric properties, mechanical properties and the like can be manufactured.

It is preferred that the crystallization-promoting layer contains crystallization-promoting material particles and a separating material containing a burnable material to be burnt by calcining, and at the crystallization-promoting layer-forming step, the green sheets where the crystallization-promoting layer is formed are stacked.

In this case, at the calcining step, the crystal-oriented ceramic in a stacked state can be made by calcining the green sheets in a stacked state. As the burnable material can be burnt at the calcining step, after the calcining step, a relatively fragile layer can be formed between the crystal-oriented ceramics in a stacked state. Thus, the crystal-oriented ceramics in a stacked state can be easily separated into single-layered crystal-oriented ceramics, for example, by allowing ultrasonic vibration to act on these crystal-oriented ceramics in a stacked state.

Therefore, in this case, many crystal-oriented ceramics can be manufactured by one time of calcining, and an efficiency of manufacturing the crystal-oriented ceramics can be increased.

It is preferred that the separating material consists of the burnable material.

In this case, the separating material can be approximately completely burnt from between layers of the crystal-oriented ceramic in a stacked state which is obtained by the calcining step. Thus, the crystal-oriented ceramics in a stacked state after calcining can be easily separated.

It is preferred that the separating material is one in which the burnable material is dispersed in the piezoelectric material with approximately the same components as for the green sheet.

In this case, the crystal-oriented ceramics in a stacked state can be formed, in which porous layers composed of the piezoelectric material are stacked between layers of the crystal-oriented ceramic after calcining. In other words, the crystal-oriented ceramics in a stacked state, which are connected with the crystal-oriented ceramics stacked adjacently via the fragile, wide-opened porous layers, can be manufactured. Therefore, the crystal-oriented ceramics in a stacked state become to be easily handled to secure a desired strength, and further become ones in which the stacked state can be easily broken by being subjected to a mechanical or physical impact.

The separating material can contain a binder, a dispersant, a plasticizer, a solvent, and fat and fatty oil, and the like as well as the burnable material.

The burnable materials include, for example, carbon particles, carbonized organic material particles, and the like. The carbonized organic material particles are ones made by carbonizing resin particles, powdered organic material particles or the like.

At the calcining step, the crystal-oriented ceramics are made by calcining the green sheet where the crystallization-promoting layer was formed.

At the calcining step, the crystal-oriented ceramics can be made, for example, by keeping them at 1080-1150° C., for 2-3 hours.

If the calcining temperature is less than 1080° C., or the calcining time is less than 2 hours, the orientation degree of the obtained crystal-oriented ceramics becomes to be insufficient, and there is a potential for a sufficient power not to be exerted, when they are applied to an injector of an automobile and the like. On the other hand, when the calcining temperature is beyond 1150° C., calcining is proceeded excessively. As a result, crystals become larger than as desired, and there is a potential for a sufficient power not to be exerted. When the calcining time is beyond 3 hours, there is a potential for the effect of manufacturing in a short time in the present invention not to be sufficiently exerted.

Next, in the second invention, the laminate-making step and the calcining step are performed. At the laminate-making step, a laminate is formed, where green sheets composed of a piezoelectric material, which forms the polycrystalline substance of the perovskite structure by calcining, and electrode-printed layers, which form the internal electrode layers by calcining, are stacked. Further, the crystallization-promoting layer containing the crystallization-promoting material particles, which allow crystal grains in the polycrystalline substance to grow at the calcining step, is formed so as to be in contact with the green sheet.

At the laminate-making step, a first step of making the green sheet where the electrode-printed layer was stackedly formed and a second step of making the laminate by stacking plural sheets of the green sheet after the first step are performed.

Thereby, the ceramic laminate, in which the internal electrode layers and the ferroelectric ceramic layers are alternately stacked, can be easily manufactured.

At the first step, concretely, electrode-printed layers can be stackedly formed on a green sheet, for example, by applying a piezoelectric material in a slurry state on a film with a desired thickness using a doctor blade method to form the green sheet, and printing a pasty electrode material containing at least one selected, for example, from Pt, Ag, Pd, Cu, Ni, Ag/Pd alloy, Cu/Ni alloy and the like on the green sheet. Further in the same manner, the laminate can be made, by preparing a plurality of green sheets on which an electrode-printed layer was printed, and stacking these green sheets at the second step so that the electrode-printed layers and the green sheets are alternately stacked.

It is preferred that at the first step, an adhesive layer exerting an adhering function at a time of stacking is formed on the electrode-printed layer of the green sheet.

In this case, adhesion between the electrode-printed layer and the green sheet at a time of stacking, namely connection between the green sheets where the electrode-printed layer was formed, can be improved due to adhering function of the adhesive layer. Thus, the laminate is excellent for adhesion of stacking areas, and can prevent faults such as releasing at the stacking area during calcining from occurring.

The adhesive layer can be formed, for example, by printing slurry with approximately the same components as for the green sheet.

At the first step, the crystallization-promoting layer is formed between the green sheet and the electrode-printed layer.

Concretely, a green sheet with a three-layered structure is made by printedly forming the crystallization-promoting layer on the above-described green sheet, and further printedly forming the electrode-printed layer on the obtained crystallization-promoting layer. Then, at the second step, the above-described laminate can be made by stacking a plurality of the green sheets with a three-layered structure.

In this case, the crystallization-promoting layer can be formed, for example, by printedly forming slurry containing the crystallization-promoting material particles with approximately the same components as for the green sheet.

Then, it is preferred that the adhesive layer is the crystallization-promoting layer containing the crystallization-promoting material particles.

Further, it is preferred that the electrode-printed layer is the crystallization-promoting layer containing the crystallization-promoting material particles.

In these cases, it becomes to be not necessary to newly make the crystallization-promoting layer, and it can be prevented to use many layers.

It is preferred that non-pole portions, where the electrode-printed layer does not exist, are partially formed around the electrode-printed layers, and at the non-pole portions, spacer layers containing a piezoelectric material with approximately the same components as for the piezoelectric material of the green sheet and the crystallization-promoting material particles, and having approximately the same thickness as for the electrode-printed layer are formed.

In this case, it can be prevented to occur faults such as cracks and releasing in the ceramic laminate after the calcining step. Further the crystal-oriented ceramic layer can be formed by allowing the crystal grains to grow and orient during calcining, since the electrode-printed layer and the spacer layer contacting the green sheet contain the crystallization-promoting material particles. Further, details are concretely described below.

When a ceramic laminate, which had non-pole portion structures inside of ends of internal electrodes, was conventionally manufactured, nothing was printed at the non-pole portion inside of ends of internal electrodes on a green sheet. Thereby, there was a level stripping between a portion where the electrode material had been printed and a portion with no printing. Therefore, it was necessary to carry out a step of contact-bonding at the stacked green sheet, and the level stripping was bridged by deforming the green sheet by adding a high pressure at the step of contact-bonding. Further, in the above-described method of contact-bonding, there was a problem that pressure loading became nonuniform, and an non-uniformity occurred in a density of the contact-bonded green sheet, and cracking or releasing easily occurred in the ceramic laminate during calcining.

On the other hand, when the spacer layers are printed at portions where non-pole portions are formed as described above, portions to become the non-pole portions in the electrode-printed layers are included, and finally no level stripping occurs at whole printing areas which become the same layers as the internal electrode layers. Therefore, it is not necessary to bridge a level stripping by contact-bonding under a high pressure, thus a step of contact-bonding is not necessarily required. Thereby, an efficiency of its manufacturing can be improved.

Even when the step of contact-bonding is needed, the laminate can be sufficiently contact-bonded under a relatively low pressure, since there is no level stripping at whole printing areas, and the electrode-printed layers can be stacked with high accuracy. Thereby, non-uniformity in a density at the contacting areas in the laminate becomes little, and occurring of cracking or releasing in the crystal-oriented ceramic layer can be inhibited.

Further, the electrode-printed layers and the spacer layers can perform a function as the crystallization-promoting layer as described above, since they contain the crystallization-promoting material particles.

### EXAMPLES

### Example 1

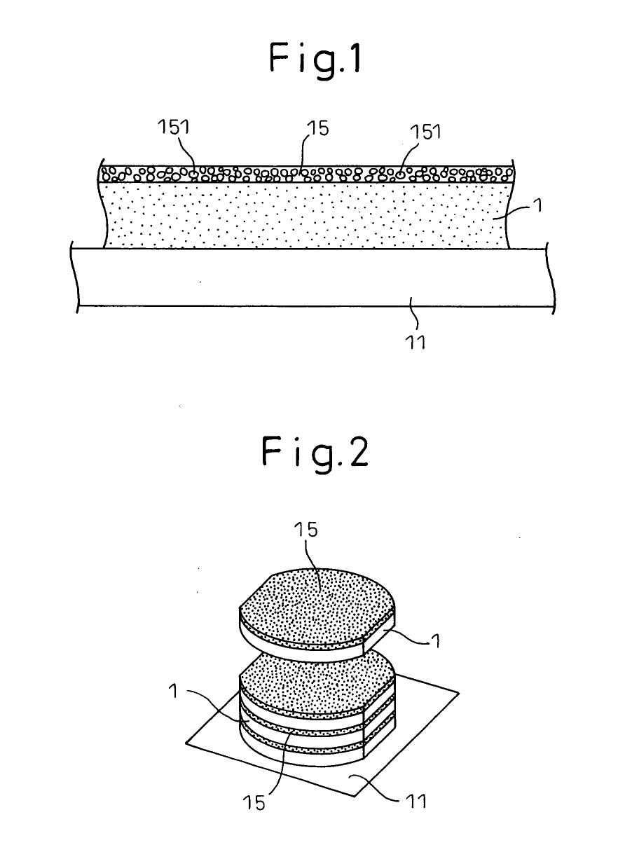

Next, an example according to the present invention is further explained using FIGS. 1-7.

In this Example, crystal-oriented ceramics are manufactured, which are composed of a polycrystalline substance comprising a perovskite structure (ABO₃) as the main component, and in which a crystal plane of each of the crystal grains constituting the polycrystalline substance is oriented.

In this Example, a sheet-making step, a crystallization-promoting layer-forming step and a calcining step are performed. At the sheet-making step, as shown in FIG. 1, a green sheet 1 composed of a piezoelectric material, which forms the polycrystalline substance of the perovskite structure, is made by calcining.

At the crystallization-promoting layer-forming step, as shown the same Figure, a crystallization-promoting layer 15 comprising crystallization-promoting material particles 151, which allow crystal grains in the polycrystalline substance to grow during calcining, is formed so as to be in contact with the green sheet 1.

At the calcining step, the crystal-oriented ceramics 10 are made by calcining the green sheets 1 where the crystallization-promoting layer 15 was formed (refer to FIG. 4).

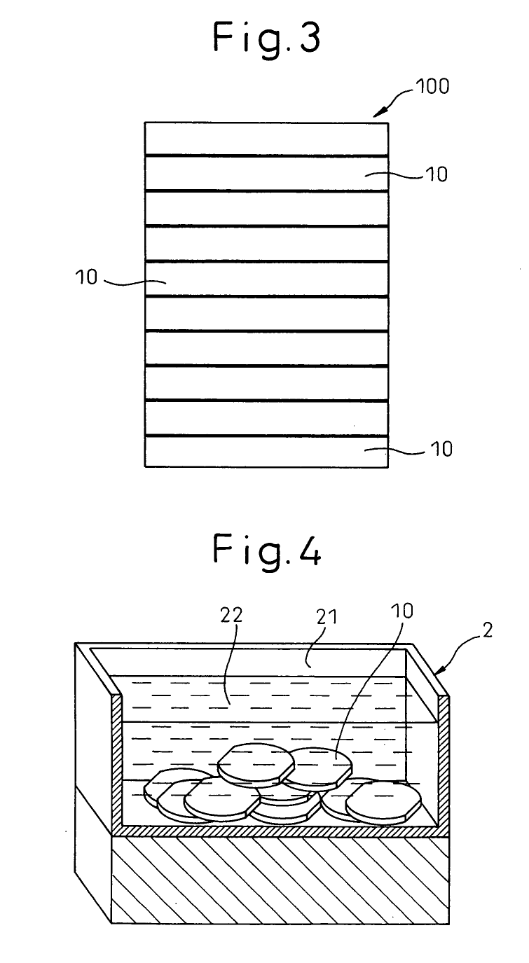

Particularly, in this Example, the crystal-oriented ceramic (a single plate) 10 is made by stacking the green sheets 1 where the crystallization-promoting layer 15 was formed (refer to FIG. 2), making a ceramic laminate 100 of the crystal-oriented ceramics 10 by calcining the stacked green sheets 1 (refer to FIG. 3), and then breaking a stacked structure of the ceramic laminate 100 (refer to FIG. 4).

Details of the method of manufacturing the crystal-oriented ceramics in this Example are described as follows.

The crystal-oriented ceramics 10 (refer to FIG. 4) of this Example are composed of the polycrystalline substance comprising a compound of the perovskite structure (ABO₃) as a main component. The crystal-oriented ceramics 10 are in the form of a plate, and has the form of a barrel with an area of 52 mm² (a diameter of 8.5 mm) and a thickness of 80 μm. According to the manufacturing method of this Example, crystal-oriented ceramics with a variety of shapes such as a circle, a quadrangle and an octangle other than the barrel of this Example can be manufactured.

In this Example, the sheet-making step is initially carried out.

In other words, as shown in FIG. 1, the green sheet 1 is made by extending slurry of the piezoelectric material in the form of a sheet. Herein, the slurry is made by adding the piezoelectric material, which forms the polycrystalline substance of the perovskite structure by being calcined, a binder, a small amount of a plasticizer and an anti-foam agent, and then dispersing them into an organic solvent. In this Example, a material in which a material composition had been adjusted so as to form a perovskite-type compound {Li_{0.04}(K_{0.5}Na_{0.5})_{0.96}} (Nb_{0.86}Ta_{0.1}Sb_{0.04})O₃ after calcining was utilized as the piezoelectric material.

The green sheet 1 with a thickness of 100 μm was formed by applying this slurry on a carrier film 11 via a doctor-blade method as shown in FIG. 1 (at the sheet-making step).

Then, a separating material containing a burnable material, carbon particles, to be burnt by calcining was prepared, and particles (with an average diameter of 0.8 μm) composed of MgO₂ as the crystallization-promoting material particles 151 were dispersed in this separating material. The separating material was made by mixing PVB (made by Denki Kagaku Kogyo Kabushiki Kaisha) as an adhesive into terpineol (made by Wako Pure Chemical Industries) as a fat and a fatty oil, stirring them for 2 minutes using a mixing-degassing apparatus, and then leaving them to stand until PVB completely dissolves, further adding carbon particles and SPAN85 (made by Wako Pure Chemical Industries) as a dispersant, and stirring them again for 1 minute.

Then, as shown in FIG. 1, the separating material, in which the crystallization-promoting material particles 151 were dispersed, was screen-printed on the green sheet 1 to form the crystallization-promoting layer 15 on the green sheet 1. As shown in the same Figure, the crystallization-promoting material particles 151 were dispersed in the crystallization-promoting layer 15. The content of the crystallization-promoting material particles 151 in the crystallization-promoting layer 15 was about 5 wt %. The amount of the crystallization-promoting material particles 151 to the piezoelectric material of 100 parts by weight was about 0.3 parts by weight.

In the same manner as described above, 100 sheets of the green sheet 1 in total were made, where the crystallization-promoting layer 15 was formed. As shown in FIG. 2, these 10 sheets of the green sheet 1 were stacked so that the crystallization-promoting layers 15 and the green sheets 1 were alternately stacked. Thereby, the green sheets 1 in a stacked state, where the crystallization-promoting layer 15 was formed, were made between adjacent green sheets 1.

Then, the green sheets 1 in a stacked state were calcined in an ambient atmosphere at a calcining temperature of 1120° C. for 2 hours, and were cooled down in a oven (at the calcinig step). In this calcinig step, the polycrystalline substances of the perovskite-type compound is formed from the piezoelectric material in the green sheet 1, and crystal grains grow via the crystallization-promoting material particles 151 in the crystallization-promoting layer 15, and orient. At the calcining process of the piezoelectric material, a burnable material in the crystallization-promoting layer 15 is burnt out.

According to such a manner, a laminate 100 of the crystal-oriented ceramics 10 shown in FIG. 3 was obtained.

Next, as shown in FIG. 4, an ultrasonic oscillator 2 comprising a containing tank 21 for containing a laminate of the crystal-oriented ceramics and an ultrasonic oscillating plate connected to a back side of its bottom (omitting to show in Figures) was prepared. The laminate 100 was kept in the containing tank 21 full of water, namely a fluid 22, and the ultrasonic oscillating plate was oscillated. Thereby, intervening structures between adjacent crystal-oriented ceramics 10 in the laminate 100 were broken, and as show in FIG. 4, single plates of the crystal-oriented ceramic 10 were made. This sample is referred to as Sample E1.

In this Example, crystal-oriented ceramics (Sample E2) were prepared in the same manner as for the above Sample E1, except for changing a kind of the crystallization-promoting material particles. Sample E2 was made by utilizing particles (with an average diameter of 0.6 μm) composed of SiC as the crystallization-promoting material particles.

In order to manufacture Sample E2, the green sheet and the separating material were made in the same manner as for Sample E1, and particles composed of SiC were dispersed in the separating material. After that, in the same manner as for Sample E1, crystal-oriented ceramics in a stacking state were made by performing the crystallization-promoting layer-forming step and the calcining step. Further, in the same manner as for Sample E1, single plates of the crystal-oriented ceramic (Sample E2) were made by breaking the intervening structures between stacked layers via an ultrasonic oscillator.

In this Example, for comparing with the Sample E1 and Sample E2, a ceramic plate (Sample C1) was made, by not utilizing the crystallization-promoting material particles.

For manufacturing Sample C1, a green sheet and a separating material were prepared in the same manner as for Sample E1, and the separating material was screen-printed on the green sheet to form separating layers. The separating layers contained no crystallization-promoting material particle. Then, in the same manner as for Sample E1, 10 sheets of the green sheet, where the separating layer was formed, were stacked to make green sheets in a stacked state. Further, the calcining step was carried out in the same manner as for Sample E1 to make ceramics in a stacked state, and then single plates of the ceramic plate (Sample C1) were made by breaking the intervening structure between stacked layers utilizing an ultrasonic oscillator in the same manner as for Sample E1.

Next, a crystal state at a surface and an orientation degree were measured for the each sample (Sample E1, Sample E2 and Sample C1) made as described above.

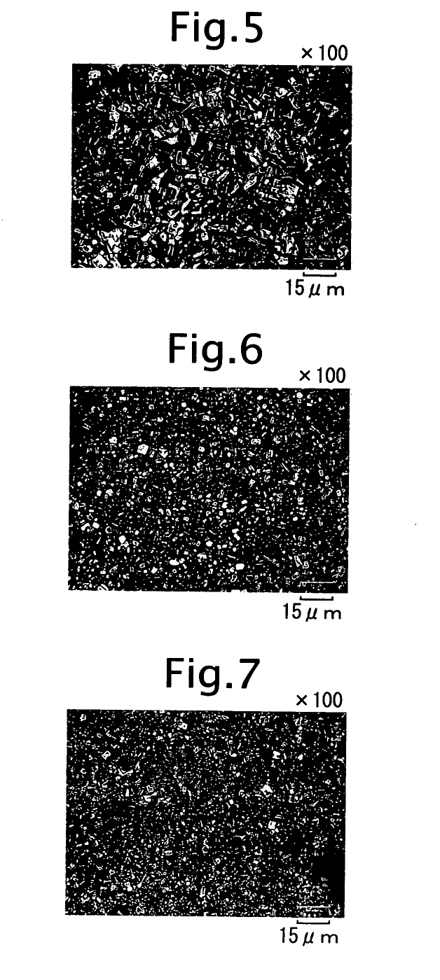

Concretely, the crystal state was observed utilizing a laser microscope (made by Olympus Corporation). The results are shown in FIGS. 5-7.

The orientation degree was measured utilizing XRD (an X-ray diffraction apparatus, made by Rigaku Corporation).

As a result, the orientation degree of Sample E1 was 19.5%, the orientation degree of Sample E2 was 29.1%, and the orientation degree of Sample C1 was 3.4%.

As found from FIGS. 5 and 7, in Sample E1 and Sample E2 which were made by forming the crystallization-promoting layer containing the crystallization-promoting material particles so as to contact the green sheet, it is realized that crystal grains constituting the polycrystalline substance grow, and crystal planes are oriented.

As found from FIGS. 5-7 and the above-described orientation degrees, it is realized that Samples E1 and E2 have higher orientation degrees than Sample C1 made without crystallization-promoting material particles.

As described above, based on this Example, it is realized that the crystal-oriented ceramics, where the crystal plane of each of the crystal grains constituting the polycrystalline substance is oriented, can be made by forming the crystallization-promoting layer containing the crystallization-promoting material particles so as to contact the green sheet, and calcining the green sheet.

### Example 2

This Example is an example of making crystal-oriented ceramics by forming a crystallization-promoting layer on a green sheet containing template particles.

The crystal-oriented ceramics in this Example are composed of a polycrystalline substance comprising a compound of a perovskite structure {Li_{0.04}(K_{0.5}Na_{0.5})_{0.96}} (Nb_{0.86}Ta_{0.1}Sb_{0.04})O₃ as a main component, are in the form of a plate, and have the form of a barrel with an area of 52 mm² (a diameter of 8.5 mm) and a thickness of 80 μm, like in Example 1.

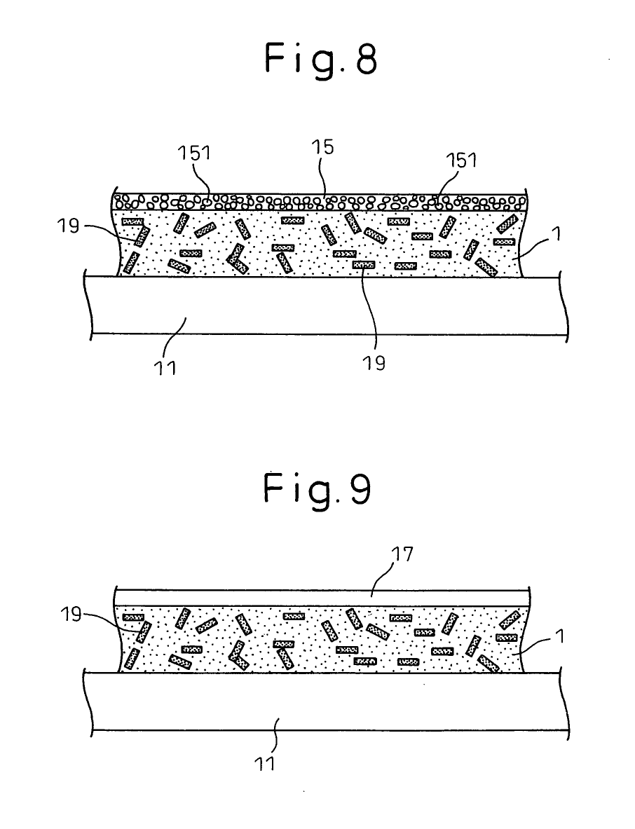

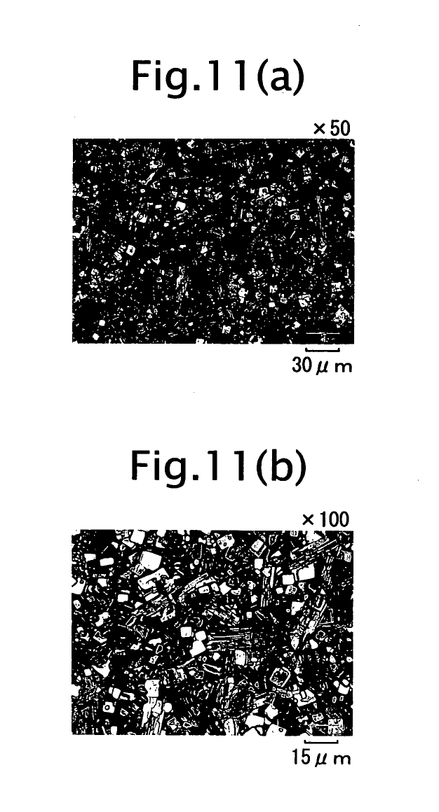

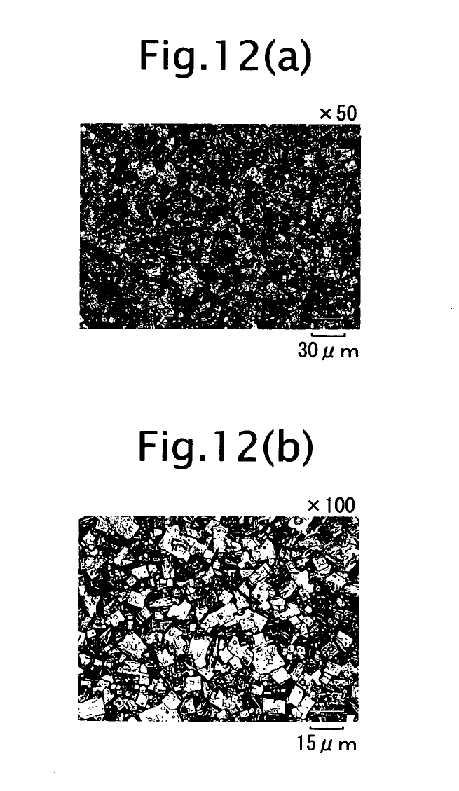

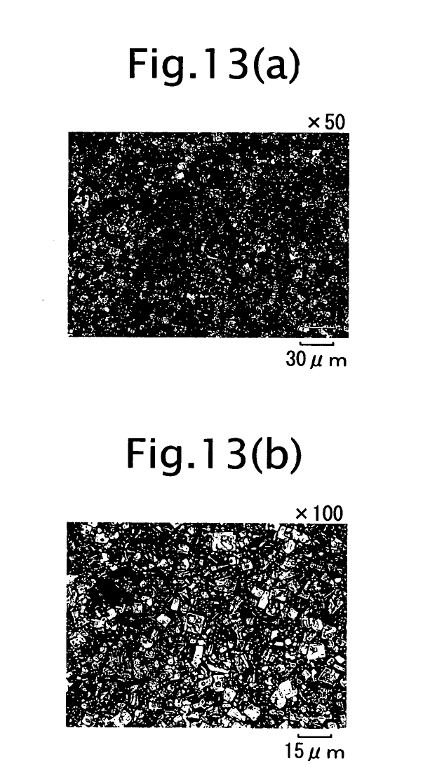

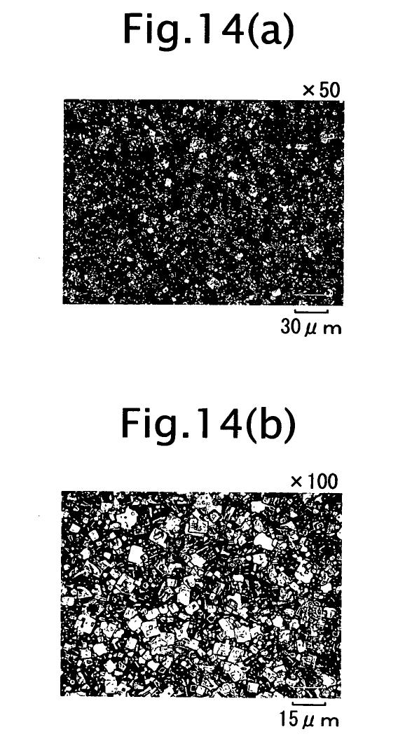

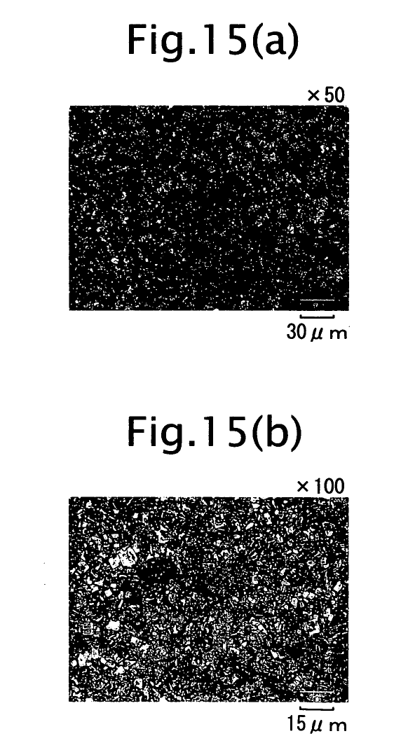

Details of the method of manufacturing the crystal-oriented ceramics in this Example are described as follows, by using FIGS. 8-15.

Initially, template particles, which were composed of a perovskite-type compound, and in which a crystal plane, having lattice coherency with a specific crystal plane (orientation plane) of a polycrystalline substance of crystal-oriented ceramics to be made was oriented, and a piezoelectric material were prepared. As the template particles and the piezoelectric material, a composition adjusted so as to form the perovskite-type compound {Li_{0.04}(K_{0.5}Na_{0.5})_{0.96}} (Nb_{0.86}Ta_{0.1}Sb_{0.04})O₃ after calcining was utilized.

Then, a piezoelectric material, a binder, a small amount of a plasticizer and an anti-foam agent were mixed, and then were dispersed into an organic solvent to make slurry of the piezoelectric material. After dispersing the template particles into this slurry, a green sheet 1 with a thickness of 100 μm was formed as shown in FIG. 8 by applying the slurry on a carrier film 11 via a doctor-blade method. As shown in the same Figure, the template particles 19 are dispersed in the green sheet 1. The content of the template particles 19 in the green sheet 1 is about 5 wt %.

Next, in the same manner as in Example 1, a separating material containing carbon particles as a burnable material was prepared, and particles (with an average diameter of 0.8 μm) composed of MgO₂ as crystallization-promoting material particles were dispersed in this separating material. The separating material made in the same manner as in Example 1 was used.

Then, in the same manner as in Example 1, the separating material, in which the crystallization-promoting material particles were dispersed, was screen-printed on the green sheet 1 to form a crystallization-promoting layer 15, as shown in FIG. 8. The content of the crystallization-promoting material particles 151 in the crystallization-promoting layer 15 is about 5 wt %. The content of the crystallization-promoting material particles 151 in the crystallization-promoting layer was about 0.3 parts by weight per 100 parts by weight of the piezoelectric material contained in the green sheet.

Further, in the same manner as in Example 1, 10 sheets of the green sheet 1, where the crystallization-promoting layer 15 was formed, were stacked to make the green sheets 1 in a stacked state (refer to FIG. 2), and a laminate 100 of crystal-oriented ceramics 10 was made by carrying out the calcining step under the same conditions as for Example 1 (refer to FIG. 3). After that, in the same manner as in Example 1, single plates of the crystal-oriented ceramic were made by breaking the intervening structure between stacked layers of the laminate 100 utilizing an ultrasonic oscillator (refer to FIG. 4). This sample is referred to as Sample E3.

In this Example, further, four kinds of crystal-oriented ceramics (Samples E4-E7) were made in the same manner as for the above-described Sample E3, except for changing a kind of the crystallization-promoting material particles.

Sample E4 was made by utilizing particles (with an average diameter of 0.6 μm) composed of SiC as the crystallization-promoting material particles.

Sample E5 was made by utilizing particles (with an average diameter of 0.8 μm) composed of TiO₂ as the crystallization-promoting material particles.

Sample E6 was made by utilizing particles (with an average diameter of 0.5 μm) composed of Al₂O₃ as the crystallization-promoting material particles.

Sample E7 was made by utilizing particles (with an average diameter of 1 μm) composed of Si₃N₄ as the crystallization-promoting material particles.

Samples E4-E7 were made in the same manner as for Sample E3 by forming the crystallization-promoting layer containing each of the crystallization-promoting material particles on the green sheet in which the template particles were dispersed, stacking the green sheets, calcining, and then breaking the structure between stacked layers utilizing an ultrasonic oscillator.

In this Example, for comparing with the Samples E3-E7, crystal-oriented ceramics (Sample C2) were made, by not utilizing the crystallization-promoting material particles.

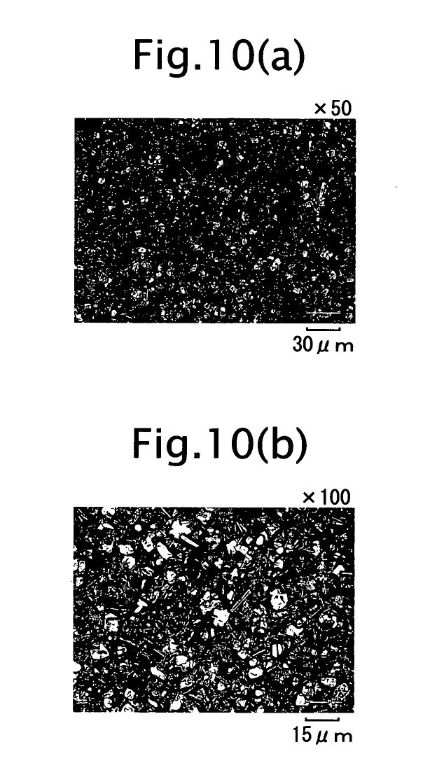

In other words, as shown in FIG. 9, a green sheet 1 in which template particles 19 were dispersed and a separating material were made in the same manner as for Sample E3, and the separating material was screen-printed on the green sheet 1 to form a separating layer 17. As shown in the same Figure, the separating layer 17 contained no crystallization-promoting material particle. Then, in the same manner as for Sample E3, 10 sheets of the green sheet 1, where the separating layer 17 was formed, were stacked to make green sheets in a stacked state (refer to FIG. 2). Then, the calcining step was carried out in the same manner as for Sample E3 to make a laminate of the crystal-oriented ceramics 10 (refer to FIG. 3), and then single plates of the ceramic plate (Sample C2) were made by breaking the intervening structure between layers of the laminate by utilizing an ultrasonic oscillator in the same manner as for Sample E3 10 (refer to FIG. 4).

Then, a crystal state at a section and an orientation degree were measured for the each sample (Samples E3-E7 and Sample C2) made as described above, in the same manner as in Example 1. Photographs of the crystal state are shown in FIGS. 10(a), 10(b), 11(a), 11(b), 12(a), 12(b), 13(a), 13(b), 14(a), 14(b), 15(a) and 15(b), and results of the orientation degree are expressed in Table 1. In Table 1, results for Samples E1, E2 and C1made in Example 1 also are expressed together.

TABLE 1

| | Kind of | with and without | |
|---|---|---|---|
| | crystallization- | template | |
| Sample | promoting material | particles in | orientation |
| No. | particles | green sheet | degree (%) |
| Sample E1 | MgO2 | without | 19.5 |
| Sample E2 | SiC | without | 29.1 |
| Sample E3 | MgO2 | with | 66.3 |
| Sample E4 | SiC | with | 63.3 |
| Sample E5 | TiO2 | with | 48.6 |
| Sample E6 | Al2O3 | with | 62.3 |
| Sample E7 | Si3N4 | with | 54.2 |
| Sample C1 | — | without | 3.4 |
| Sample C2 | — | with | 53.4 |

As known from FIGS. 10(a), 10(b), 11(a), 11(b), 12(a), 12(b), 13(a), 13(b), 14(a), 14(b), 15(a) and 15(b), it is realized that the crystal grains constituting the polycrystalline substance grow, and the crystal plane is oriented, in the crystal-oriented ceramics of Samples E3-E7 made by forming the crystallization-promoting layer containing the crystallization-promoting material particles on the green sheet, in comparison with the crystal-oriented ceramics of Sample C2 made without forming a crystallization-promoting layer. As found from Table 1, it is realized that Samples E3-E7 have the same or more excellent orientation degree in comparison with Sample C3. Particularly, it is realized that Sample E3 where MgO₂ was utilized as a crystallization-promoting material, Sample E4 utilizing SiO, Sample E6 utilizing Al₂O₃, and Sample E7 utilizing Si₃N₄ offer higher orientation degree than Sample C2 made without a crystallization-promoting layer.

As found by comparing Sample E3 made by dispersing the template particles in the green sheet and Sample E1 made without template particles, or Sample E4 and Sample E2 in the same relation, it is realized that the orientation degree of the crystal-oriented ceramics can be further improved by allowing template particles to be contained in the green sheet.

### Example 3

In Example 1 and Example 2, the crystal-oriented ceramics were made by forming the crystallization-promoting layer on the green sheet. This Example is one where crystal-oriented ceramics are made by forming a crystallization-promoting layer between green sheets.

Concretely, two green sheets with a thickness of 100 μm were made by utilizing slurry, in the same manner as in Example 1.

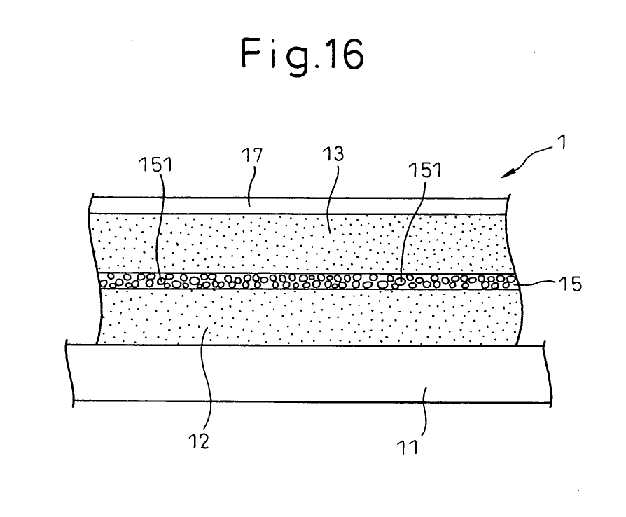

Then, particles (with an average diameter of 0.8 μm) composed of MgO₂ as crystallization-promoting material particles were dispersed in slurry which had been utilized for the green sheet, and as shown in FIG. 16, a crystallization-promoting layer 15 was formed by applying the slurry at a thickness of about 10μm on one of the green sheets 12. After that, the other green sheet 13 was stacked on the crystallization-promoting layer 15 to make a three-layered green sheet 1. As shown in the same Figure, the crystallization-promoting layer 15 of this Example contains a piezoelectric material with approximately the same components as the green sheets 12 and 13, and crystallization-promoting particles 151, and is formed at between the green sheets 12 and 13 so as to contact the green sheets 12 and 13.

Further, a separating material was prepared in the same manner as in Example 1, and a separating layer 17 was formed by screen-printing this separating material on the three-layered green sheet 1. Then, in the same manner, ten sheets of the three-layered green sheet 1 where the separating layer 17 was formed were made, and stacked green sheets were made by stacking these three-layered green sheets (refer to FIG. 2).

Then, in the same manner as in Example 1, a laminate of crystal-oriented ceramics was made by performing a calcining step (refer to FIG. 3), and single plates of the crystal-oriented ceramic were made by breaking an intervening structure between stacked layers utilizing an ultrasonic oscillator (refer to FIG. 4).

In the crystal-oriented ceramics obtained as described above, a crystal plane of each of the crystal grains constituting the polycrystalline substance was oriented like in Sample E1 and Sample E2 of Example 1.

The single plates of the crystal-oriented ceramic made in this Example had an approximately two times thickness of one crystal-oriented ceramic made in Examples 1 and 2, since they were made by forming the crystallization-promoting layer between two sheets of the green sheet.

### Example 4

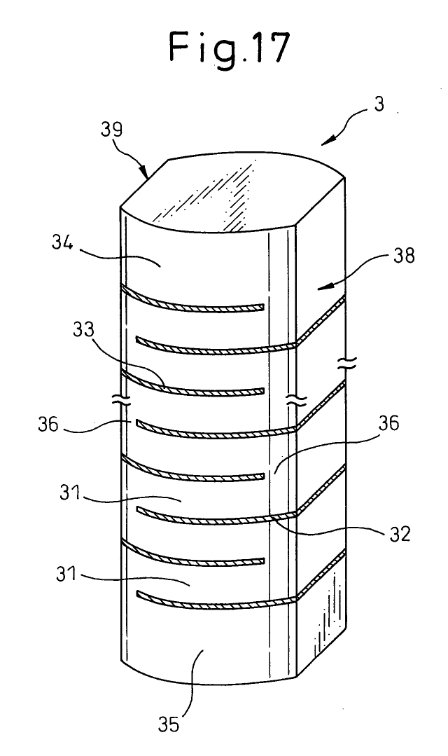

This Example is, as shown in FIG. 17, an example of making a ceramic laminate 3 where crystal-oriented ceramic layers 31 and internal electrode layers 32, 33 are alternately stacked. The crystal-oriented ceramic layers 31 are composed of a polycrystalline substance comprising a perovskite structure (ABO₃) as a main component. In the crystal-oriented ceramic layers 31, a crystal plane of each of the crystal grains constituting the polycrystalline substance is oriented.

At both ends of the ceramic laminate 3 of this Example in a stacking direction, protective layers 34, 34 are formed with approximately the same material as for the crystal-oriented ceramic layers 31.

At a side area 38 of the ceramic laminate 3, external periphery ends of the internal electrode layers 32 are exposed, and external periphery ends of the internal electrode layers 33 are not exposed to form portions without an electrode (non-pole portions 36). On the other hand, at a side area 39, external periphery ends of the internal electrode layers 33 are exposed, and external periphery ends of the internal electrode layers 32 are not exposed to form portions without an electrode (non-pole portions 36). The internal electrode layers 32 and the internal electrode layers 33 are alternately disposed in the stacking direction, and the ceramic laminate 3 of this Example has a so-called partially non-pole portion structure.

Although the partially non-pole portion structure was employed as a structure of the ceramic laminate 3 in this Example, a so-called entirely non-pole portion structure or other various structures can be utilized.

In a manufacturing method of the ceramic laminate 3 of this Example, a laminate-making step and a calcining step are performed.

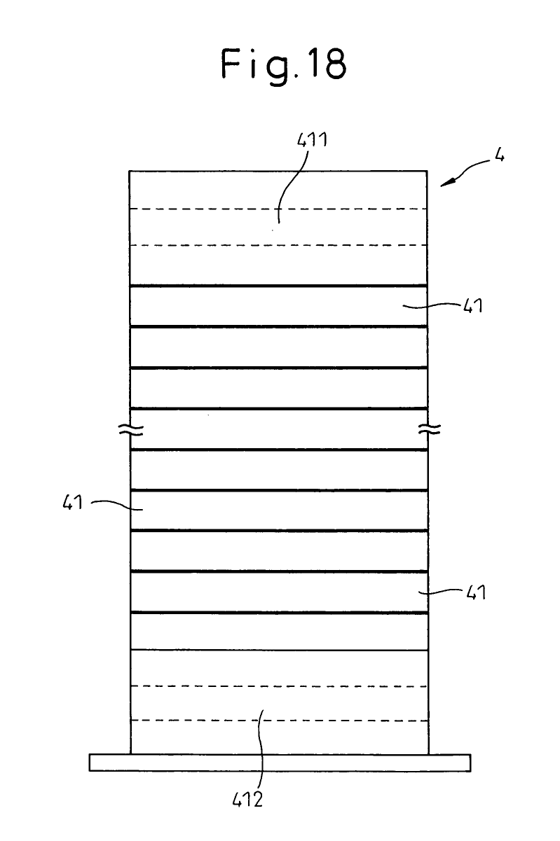

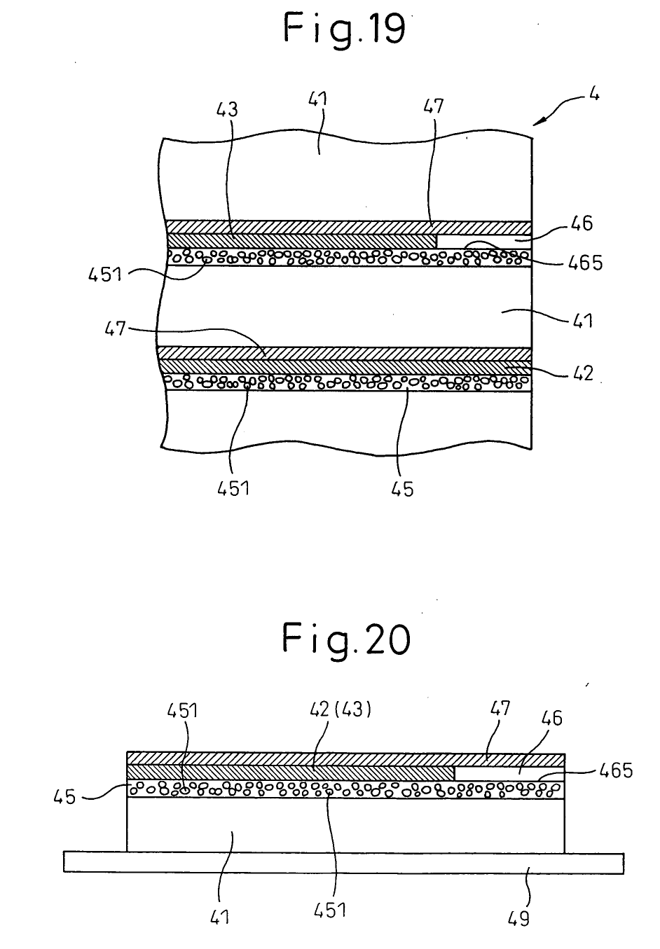

At the laminate-making step, as shown in FIGS. 18 and 19, a laminate 4 is made, where green sheets 41 composed of a piezoelectric material, which forms the polycrystalline substance of the perovskite structure by calcining, and electrode-printed layers 42 and 43, which form the internal electrode layers 32 and 33 by calcining (refer to FIG. 17), are stacked. In the laminate 4, the crystallization-promoting layers 45 containing the crystallization-promoting material particles 451, which allow crystal grains in a polycrystalline substance to grow during calcining, are formed so as to be in contact with the green sheet 41. Particularly, in the laminate-making step of this Example, a first step and a second step are carried out. At the first step, as shown in FIG. 20, the green sheet 41 is made, where an electrode-printed layer 42 (43) is stackedly formed. At the second step, as shown in FIGS. 18 and 19, the laminate 4 is made by stacking a plurality of green sheets 41 after the first step.

At the calcining step, the laminate 4 is calcined to make the ceramic laminate 3 shown in FIG. 17.

Details of the method of manufacturing the ceramic laminate of this Example are described as follows.

Initially, a piezoelectric material, which forms the polycrystalline substance of the perovskite structure by being calcined, a binder, a small amount of a plasticizer and an anti-foam agent were added, and then dispersed into an organic solvent to make slurry of the piezoelectric material. In this Example, as in Example 1, a material in which a material composition had been adjusted so as to form a perovskite-type compound {Li_{0.04}(K_{0.5}Na_{0.5})_{0.96}} (Nb_{0.86}Ta_{0.1}Sb_{0.04})O₃ after calcining was utilized as the piezoelectric material.

Then, a green sheet 41 with a thickness of 100 μm was formed in the same manner as in Example 1 by applying this slurry on a carrier film 49 via a doctor-blade method as shown in FIG. 20. Particles (with an average diameter of 0.8 μm) composed of MgO₂ as the crystallization-promoting material particles were dispersed in the slurry used for making the green sheet 41, and a crystallization-promoting layer 45 was formed by applying this slurry at a thickness of about 10 μm on the green sheet 41.

Further, the green sheet 41 was cut out into a piece with a desired size, and an electrode material was printed at a desired position to form an electrode-printed layer 42 (43). The electrode material was printed on one surface of the green sheet 41 so as to allow the material to arrive only one side area of the green sheet 41. At this time, on the other side, a non-forming portion 465 which becomes the non-pole portion 36 after calcining is formed (refer to FIG. 17). A pasty Ag/Pd alloy was used as the electrode material.

In this Example, a spacer layer 46 with approximately the same thickness as for the electrode-printed layer 42 (43) was printed on the non-forming portion 465. The spacer layer 46 was formed by printing the slurry used for making the green sheet 41 at the non-forming portion 465 with approximately the same thickness as for the electrode-printed layer 42 (43).

Then, an adhesive layer 47, which exerts an adhering function at a time of stacking, is formed on the electrode-printed layer 42 (43) and the spacer layer 46. The adhesive layer 47 was formed by printing the slurry for making the green sheet 41 on the electrode-printed layer 42 (43) and the spacer layer 46.

Thereby, as shown in FIG. 20, the green sheet 41 was made, where the crystallization-promoting layer 45, the electrode-printed layer 42 (43), the spacer layer 46 and the adhesive layer 47 were stackedly formed. Further, 100 sheets of the green sheet 41 were made in the same manner. As shown in the same Figure, crystallization-promoting material particles 451 are dispersed in the crystallization-promoting layer 45, and the content of the crystallization-promoting material particles 451 in the crystallization-promoting layer 45 is about 5 wt %. The amount of the crystallization-promoting material particles 451 to the piezoelectric material of 100 parts by weight of the green sheet 41 was about 0.3 parts by weight.

Next, as shown in FIGS. 18 and 19, the laminate 4 was made by stacking these 100 sheets of the green sheet 41 so that a layer of the green sheets 41 and the electrode-printed layers 42 (43) were alternately stacked. At this time, they were alternately stacked so that the electrode-printed layers 42 and the electrode-printed layers 43 alternately arrive at a right end and a left end.

Then, a sheet with a thickness of 100 μm was formed using the slurry, which had been utilized for making the green sheet, via a doctor-blade method to make 6 sheets of a green sheet for a protective layer. As shown in FIG. 18, every three sheets of these 6 sheets of the green sheets for the protective layer 411, 412 were stacked at both ends of the laminate 4 in the stacking direction, in other words, at the top stage and at the bottom stage. Neither electrode-printed layer and spacer layer was formed at the green sheets for the protective layer 411, 412.

Thereby, the laminate 4 was made as shown in FIGS. 18 and 19. As shown in these Figures, the crystallization-promoting layer 45 containing the crystallization-promoting material particles 451 is formed in the laminate 4.

Further, the laminate 4 was heated to perform degreasing. Heating to degrease was performed under conditions of gradually elevating a temperature to 400° C. over 70 hours, and maintaining the temperature for 5 hours. Thereby, 90% or more of a binder resin contained in the green sheet and the like can be removed.

Then, the laminate 4 after degreasing was calcined. Calcining was performed in the ambient atmosphere under conditions of gradually elevating a temperature to 1120° C. over 70 hours, and maintaining the temperature for 2 hours.

As a result, as shown in FIG. 17, the ceramic laminate 3 was obtained, where the crystal-oriented ceramic layers 31 and the internal electrode layers 32, 33 were alternately stacked. In the ceramic laminate 3, the crystal-oriented ceramic layer 31 are composed of a polycrystalline substance comprising a compound of a perovskite structure {Li_{0.04}(K_{0.5}Na_{0.5})_{0.96}} (Nb_{0.86}Ta_{0.1}Sb_{0.04})O₃ as a main component, and a crystal plane of each of the crystal grains constituting the polycrystalline substance is oriented. Therefore, the ceramic laminate of this Example can be utilized as a laminate-type piezoelectric element with a high power, and can be applied to an injector for injecting fuel and the like.

### Example 5

This Example is one where a ceramic laminate was made by formulating crystallization-promoting material particles in electrode-printed layers which become internal electrode layers after calcining.

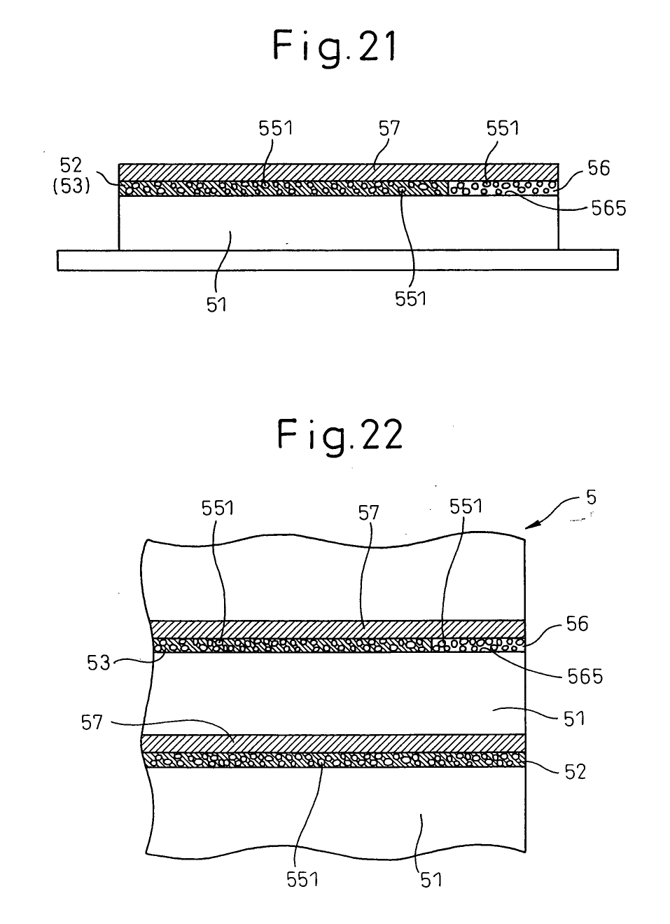

Concretely, at first, a green sheet 51 as shown in FIG. 21 was made in the same manner as in Example 4.

Then, an electrode material was made by dispersing particles (with an average diameter of 0.8 μm) composed of MgO₂ as crystallization-promoting material particles in a pasty Ag/Pd alloy, cutting out the green sheet 51 into pieces with a desired size, and then printing the electrode material at desired positions to form an electrode-printed layer 52 (53). A spacer layer 56 was formed by dispersing particles (with an average diameter of 0.8 μm) composed of MgO₂ as crystallization-promoting material particles in the slurry used to make the green sheet 41, and printing this slurry at a non-forming portion 565 of the green sheet 51.

Further, in the same manner as in Example 4, an adhesive layer 57, which exerts an adhering function at a time of stacking, is formed on the electrode-printed layer 52 (53) and a spacer layer 56.

In this manner, as shown in FIG. 21, the green sheet 51 was made, where the electrode-printed layer 52 (53), the spacer layer 56 and the adhesive layer 57 were stackedly formed. As shown in the same Figure, crystallization-promoting material particles 551 are dispersed in the electrode-printed layer 52 (53) and the spacer layer 56, and the electrode-printed layer 52 (53) and the spacer layer 56 form a crystallization-promoting layer. Both contents of the crystallization-promoting material particles in the electrode-printed layer 52 (53) and of the crystallization-promoting material particles in the spacer layer 56 are about 5 wt %. The amount of the crystallization-promoting material particles to the piezoelectric material of 100 parts by weight of the green sheet 41 was about 0.3 parts by weight.

Next, in the same manner as in Example 4, a laminate was made by preparing 100 sheets of a green sheet where an electrode-printed layer, a spacer layer and an adhesive layer were stackedly formed, and stacking them. Further, the same laminate as in Example 4 was made by stacking protective green sheets at both ends of the laminate in the stacking direction, namely at the top stage and at the bottom stage. As shown in FIG. 22, in the laminate 5 of this Example, the crystallization-promoting layers (the electrode-printed layer 52 (53) and the spacer layer 56) containing crystallization-promoting material particles 551 are formed so as to contact the green sheet 51.

Further, in the same manner as in Example 4, the laminate was heated to perform degreasing, and then the laminate was clacined to make a ceramic laminate.

In this Example, as described above, the ceramic laminate was made by dispersing crystallization-promoting material particles in the electrode-printed layer and the spacer layer, and reducing these electrode-printed layer and spacer layer to the crystallization-promoting layer.

As a result, also in this Example, the ceramic laminate, in which the crystal plane of each of the crystal grains of the polycrystalline substance constituting the crystal-oriented ceramic layer was oriented, could be obtained

### Example 6

This Example is one where a ceramic laminate was made by formulating crystallization-promoting material particles in an adhesive layer.

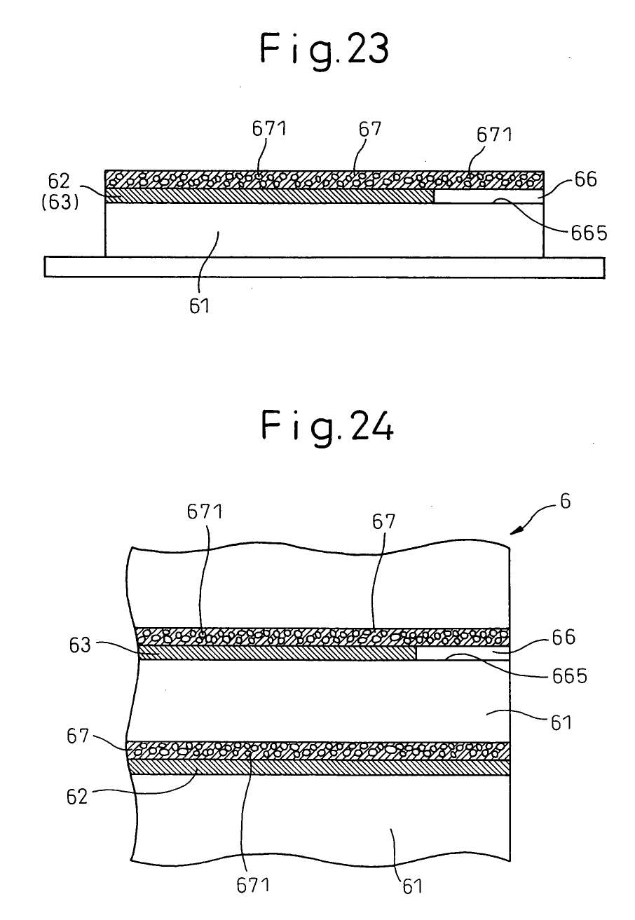

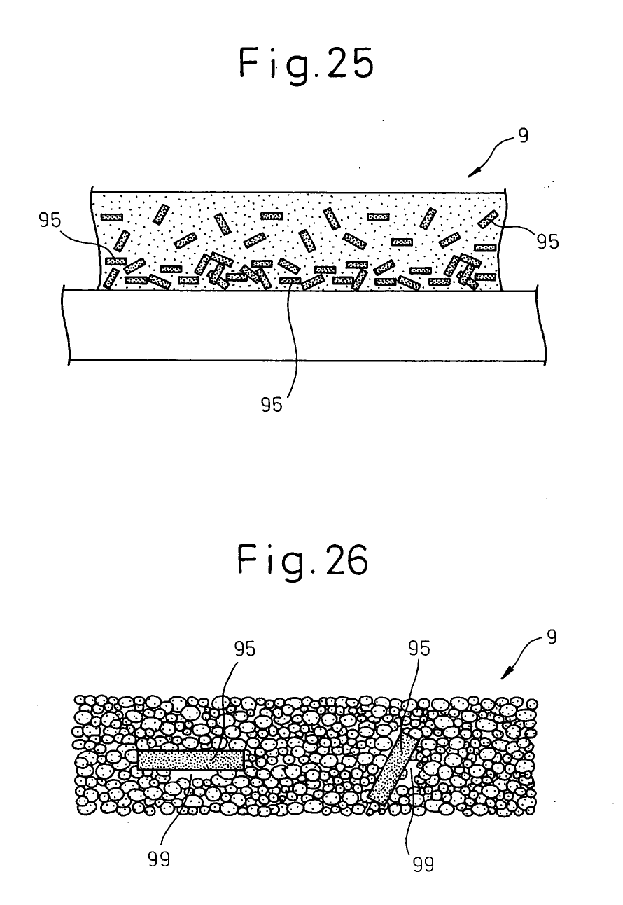

Concretely, in the same manner as in Example 4, as shown in FIG. 23, a green sheet 61 was made first.

Then, an electrode-printed layer 62 (63) was formed by cutting out the green sheet 61 into a piece with a desired size, and then printing an electrode material (a pasty Ag/Pd alloy) at a desired position. A spacer layer 66 was formed by printing slurry used to make the green sheet 61 at a non-forming portion 665 of the green sheet in the same manner as in Example 4.

Then, particles (with an average diameter of 0.8 μm) composed of MgO₂ as the crystallization-promoting material particles were dispersed in the slurry used for making the green sheet, and an adhesive layer 67 was formed by applying this slurry on the electrode-printed layer 62 (63) and the spacer layer 66.

In such a manner, as shown in FIG. 23, the green sheet 61 was made, where the electrode-printed layer 62 (63), the spacer layer 66 and the adhesive layer 67 were stackedly formed. As shown in the same Figure, in the adhesive layer 67 of this Example, the crystallization-promoting material particles 671 are dispersed, and the adhesive layer 67 forms the crystallization-promoting layer. The content of the crystallization-promoting material particles in the adhesive layer 67 is about 5 wt %. The amount of the crystallization-promoting material particles 671 to the piezoelectric material of 100 parts by weight of the green sheet 61 was about 0.3 parts by weight.

Next, in the same manner as in Example 4, a laminate was made by preparing 100 sheets of a green sheet where an electrode-printed layer, a spacer layer and an adhesive layer were stackedly formed, and stacking them. Further, the same laminate as in Example 4 was made by stacking protective green sheets at both ends of the laminate in the stacking direction, namely at the top stage and at the bottom stage. As shown in FIG. 24, in the laminate 6 of this Example, the crystallization-promoting layers (the adhesive layer 67) containing crystallization-promoting material particles 671 are formed so as to contact the green sheet 61.

Further, in the same manner as in Example 4, the laminate was heated to perform degreasing, and then the laminate was clacined to make a ceramic laminate.

In this Example, as described above, the ceramic laminate was made by dispersing crystallization-promoting material particles in the adhesive layer, and reducing this adhesive layer to the crystallization-promoting layer.

As a result, also in this Example, the ceramic laminate, in which the crystal plane of each of the crystal grains of the polycrystalline substance constituting the crystal-oriented ceramic layer was oriented, could be obtained

We claim:

1. A method for manufacturing a crystal-oriented ceramic, which is composed of a polycrystalline substance comprising a perovskite structure (ABO₃) as a main component, and in which a crystal plane of each of crystal grains constituting the polycrystalline substance is oriented, comprising
a sheet-making step of making a green sheet composed of a piezoelectric material which produces the polycrystalline substance of the perovskite structure by being calcined,
a crystallization-promoting layer-forming step of forming a crystallization-promoting layer comprising crystallization-promoting material particles, which allow crystal grains in the polycrystalline substance to grow at a time of calcining, so as to be in contact with the green sheet, and
a calcining step of making the crystal-oriented ceramic by calcining the green sheets where the crystallization-promoting layer was formed.

2. The method for manufacturing a crystal-oriented ceramic according to claim 1, characterized in that the crystallization-promoting material particles are composed of one or more selected from TiO₂, MgO₂, Al₂O₃, Si₃N₄ and SiC.

3. The method for manufacturing a crystal-oriented ceramic according to claim 1, characterized in that the crystallization-promoting layer contains the crystallization-promoting material particles at 2-10 wt %.

4. The method for manufacturing a crystal-oriented ceramic according to claim 1, characterized in that an average diameter of the crystallization-promoting material particles is 0.2-2 μm.

5. The method for manufacturing crystal a oriented-ceramic according to claim 1, characterized in that the green sheet is composed of a perovskite compound, and contains template particles in which a crystal plane having lattice coherency with a specific crystal plane of each of the crystal grains constituting the polycrystalline substance is oriented.

6. The method for manufacturing a crystal-oriented ceramic according to claim 1, characterized in that the crystallization-promoting layer contains a piezoelectric material with approximately the same components as in the piezoelectric material of the green sheet.

7. The method for manufacturing a crystal-oriented ceramic according to claim 1, characterized in that the crystallization-promoting layer contains crystallization-promoting material particles and a separating material containing a burnable material to be burnt by calcining, and at the crystallization-promoting layer-forming step, the green sheets where the crystallization-promoting layer is formed are stacked.

8. A method for manufacturing a ceramic laminate, which is composed of a polycrystalline substance comprising a perovskite structure (ABO₃) as a main component, and in which crystal-oriented ceramic layers, wherein a specific crystal plane of each of crystal grains constituting the polycrystalline substance is oriented, and internal electrode layers are alternately stacked, comprising
a laminate-making step of making a laminate in which a green sheet composed of a piezoelectric material, which produces the polycrystalline substance of the perovskite structure by being calcining, and electrode-printed layers, which form the internal electrode layers by calcining, are stacked, and
a calcining step of making the ceramic laminate by calcining the laminate,
and, at the laminate-making step, a crystallization-promoting layer containing crystallization-promoting material particles, which allow crystal grains in the polycrystalline substance to grow at a time of calcining, is formed so as to be in contact with the green sheet.

9. The method for manufacturing a ceramic laminate according to claim 8, characterized in that the crystallization-promoting material particles are composed of one or more selected from TiO₂, MgO₂, Al₂O₃, Si₃N₄ and SiC.

10. The method for manufacturing a ceramic laminate according to claim 8, characterized in that the crystallization-promoting layer contains the crystallization-promoting material particles at 2-10 wt %.

11. The method for manufacturing a ceramic laminate according to claim 8, characterized in that an average diameter of the crystallization-promoting material particles is 0.2-2 μm.

12. The method for manufacturing a ceramic laminate according to claim 8, characterized in that the green sheet is composed of a perovskite compound, and contains template particles in which a crystal plane having lattice coherency with a specific crystal plane of the crystal grains constituting the polycrystalline substance is oriented.

13. The method for manufacturing a ceramic laminate according to claim 8, characterized in that at the laminate-making step, a first step of making the green sheet where the electrode-printed layer was stackedly formed and a second step of making the laminate by stacking plural sheets of the green sheet after the first step are performed.

14. The method for manufacturing a ceramic laminate according to claim 13, characterized in that at the first step, an adhesive layer exerting an adhering function at a time of stacking is formed on the electrode-printed layer of the green sheet.

15. The method for manufacturing a ceramic laminate according to claim 13, characterized in that at the first step, the crystallization-promoting layer is formed between the green sheet and the electrode-printed layer.

16. The method for manufacturing a ceramic laminate according to claim 14, characterized in that the adhesive layer is the crystallization-promoting layer containing the crystallization-promoting material particles.

17. The method for manufacturing a ceramic laminate according to claim 8, characterized in that the electrode-printed layer is the crystallization-promoting layer containing the crystallization-promoting material particles.

18. The method for manufacturing a ceramic laminate according to claim 17, characterized in that non-pole portions, where the electrode-printed layer does not exist, are partially formed around the electrode-printed layers, and at the non-pole portions, spacer layer containing a piezoelectric material with approximately the same components as in the piezoelectric material of the green sheet and the crystallization-promoting material particles, and having approximately the same thickness as of the electrode-printed layer is formed.
